(19) United States
(12) Patent Application Publication
(10) Pub. No.: US 2007/0091955 A1
(43) Pub. Date: Apr. 26, 2007

(54) SEMICONDUCTOR LASER DEVICE AND OPTICAL PICKUP APPARATUS USING THE SAME

(75) Inventor: Toru TAKAYAMA, Nara-shi, Nara (JP)

Correspondence Address: HAMRE, SCHUMANN, MUELLER & LARSON P.C., P.O. BOX 2902-0902, MINNEAPOLIS, MN, 55402, US

(73) Assignee: MATSUSHITA ELECTRIC INDUSTRIAL CO., LTD., Osaka (JP)

(21) Appl. No.: 11/563,506

(22) Filed: Nov. 27, 2006

Related U.S. Application Data
(63) Continuation of application No. 10/796,704, filed on Mar. 9, 2004.

(30) Foreign Application Priority Data
Mar. 17, 2003 (JP) 2003-072703

(51) Int. Cl. H01S 5/00

(52) U.S. Cl. 372/43.01

(57) ABSTRACT

A semiconductor laser device is provided, in which an optical axis of a far-field pattern (FFP) is stabilized and which is capable of oscillating in a fundamental transverse mode up to a high output. An optical pickup apparatus also is provided, in which an optical axis of an FFP is stabilized and which is capable of being operated in fundamental transverse mode oscillation up to a high output. A semiconductor laser device is formed on a tilted substrate composed of a compound semiconductor, and includes an active layer and two cladding layers interposing the active layer therebetween. One of the cladding layers forms a mesa-shaped ridge. The ridge includes a first region where a width of a bottom portion of the ridge is substantially constant and a second region where the width of the bottom portion of the ridge is varied continuously. The second region is placed between the first region and an end face in an optical path.

### CROSS REFERENCE TO RELATED APPLICATIONS

This application is a Continuation of application Ser. No. 10/796,704, filed Mar. 9, 2004, which application is incorporated herein by reference.

### BACKGROUND OF THE INVENTION

1. Field of the Invention

The present invention relates to a semiconductor laser device and an optical pickup apparatus using the same.

2. Description of the Related Art

Currently, a semiconductor laser device (hereinafter, which also may be referred to as a “semiconductor laser”) is used widely in various fields. Above all, an AlGaInP semiconductor laser can emit laser light in a wavelength band of 650 nm, so that it is used widely as a light source in the field of an optical disk system. As a typical example, a semiconductor laser is known, which has a double-hetero structure including an active layer and two cladding layers interposing the active layer therebetween, and in which one of the cladding layers forms a mesa-shaped ridge. Such a semiconductor laser is disclosed, for example, in JP 2001-196694 A and the like.

FIG. 18 shows an example of an AlGaInP semiconductor laser having 20 a double-hetero structure. The mole fraction of each layer described below will be omitted. In the semiconductor laser shown in FIG. 18, an n-type GaAs buffer layer 102, an n-type GaInP buffer layer 103, and an n-type (AlGa)InP cladding layer 104 are stacked successively on an n-type GaAs substrate 101 having a plane tilted by 15° in a [011] direction from a (100) plane as a principal plane. Furthermore, a strain quantum well active layer 105, a p-type (AlGa)InP first cladding layer 106, a p-type (or undoped) GaInP etching stop layer 107, a p-type (AlGa)InP second cladding layer 108, a p-type GaInP intermediate layer 109, and a p-type GaAs cap layer 110 are stacked on the n-type (AlGa)InP cladding layer 104. Herein, the p-type (AlGa)InP second cladding layer 108, the p-type GaInP intermediate layer 109, and the p-type GaAs cap layer 110 are formed as a ridge having a forward mesa shape on the p-type GaInP etching stop layer 107. Furthermore, an n-type GaAs current blocking layer 111 is formed on the p-type GaInP etching stop layer 107 and on the side surfaces of the ridge, and a p-type GaAs contact layer 112 is stacked on the n-type GaAs current blocking layer 111 and the p-type GaAs cap layer 110. The strain quantum well active layer 105 is composed of an (AlGa)InP layer and a GaInP layer.

In the semiconductor laser shown in FIG. 18, a current injected from the p-type GaAs contact layer 112 is confined to the ridge portion by the n-type GaAs current blocking layer 111, and is injected in a concentrated manner into the strain quantum well active layer 105 in the vicinity of a ridge bottom portion. Thus, in spite of a small amount (tens of mA) of an injected current, a population inversion state of carriers required for laser oscillation is achieved. At this time, light is generated due to the re-combination of carriers. Then, in a direction vertical to the strain quantum well active layer 105, the light is confined by the n-type (AlGa)InP cladding layer 104 and the p-type (AlGa)InP first cladding layer 106, and in a direction parallel to the strain quantum well active layer 105, light confinement is performed by the GaAs current blocking layer 111 so as to absorb the generated light. Consequently, when the gain obtained by the injected current exceeds the loss in a waveguide in the strain quantum well active layer 105, laser oscillation occurs.

Furthermore, in the AlGaInP semiconductor laser shown in FIG. 18, generally, in order to obtain satisfactory temperature characteristics T₀, a GaAs substrate having a plane tilted in a range of 7° to 15° in a [011] direction from a (100) plane as a principal plane is used widely (see, for example, JP 2001-196694 A). As the value of the temperature characteristics T₀ is larger, the dependency of a semiconductor laser on temperature is decreased, whereby a more practical semiconductor laser is obtained.

However, in the case of using a substrate having a plane tilted by θ° from a particular crystal plane as a principal plane as in the semiconductor laser shown in FIG. 18, the cross-sectional shape of a ridge formed by using only chemical wet etching is right-left asymmetrical, seen in an optical path direction (waveguide direction). For example, in the example shown in FIG. 18, angles formed by the principal plane of the substrate and the side surfaces of the ridge are θ₁°=54.7°−θ°, and θ₂°=54.7°+θ°.

The cross-sectional shape of a ridge also may be set to be right-left symmetrical, seen in an optical path direction, by forming the ridge by physical etching such as ion beam etching. However, in this case, physical damage remains on the side surfaces of the ridge, whereby a current leaks at an interface between the side surfaces of the ridge and the current blocking layer to degrade a current confinement effect. Aprocedure of chemically etching the side surfaces of a ridge after the ridge is formed by physical etching and before forming a current blocking layer also is considered. However, in this case, there is a high possibility that the cross-sectional shape of the ridge becomes right-left asymmetrical, seen in an optical path direction.

In the case where the cross-sectional shape of a ridge is right-left asymmetrical, seen in an optical path direction, the cross-sectional shape of a waveguide also becomes right-left asymmetrical, seen in an optical path direction. Then, a shift (ΔP) in a horizontal direction is likely to be caused between the peak center position of a carrier distribution pattern in the active layer and the peak center position of an intensity distribution pattern of light propagating through the waveguide. Generally, when the amount of an injected current is increased to set a semiconductor laser to a high-output state, the carrier concentration is relatively decreased in a region where the light intensity distribution inside the active layer becomes maximum, and spatial hole burning of carriers is likely to occur. In the case where hole burning occurs, as ΔP is larger, the asymmetry of the carrier distribution pattern tends to be increased. Therefore, in the semiconductor laser with large ΔP (i.e., a semiconductor laser in which the cross-sectional shape of a ridge, seen in an optical path direction, is further asymmetrical), the oscillation position of light is unstable in a high-output state, whereby bending i.e., “kink”) of current—light output characteristics is likely to occur.

Conventionally, even when the cross-sectional shape of a waveguide is asymmetrical, if a light output is at a level of about 50 mW, fundamental transverse mode oscillation can be maintained as a semiconductor laser. For example, in the case of using a semiconductor laser as a light source of an optical disk system, to obtain fundamental transverse mode oscillation is very important for condensing oscillating laser light onto a recording medium such as an optical disk to a lens diffraction-limited degree. However, in the future, in the case of realizing an optical disk system capable of reading/writing data at a high speed, it is desired to realize a semiconductor laser that enables fundamental transverse mode oscillation to be obtained stably even at a high-output state of 100 mW or more.

Therefore, there is a demand for a semiconductor laser, formed on a substrate having a plane tilted from a particular crystal plane as a principal plane, and including a mesa-shaped ridge, in which fundamental transverse mode oscillation can be performed stably up to a higher output.

### SUMMARY OF THE INVENTION

A semiconductor laser device of the present invention is formed on a tilted substrate composed of a compound semiconductor, and includes an active layer and two cladding layers interposing the active layer therebetween. One of the cladding layers forms a mesa-shaped ridge. The ridge includes a first region where a width of a bottom portion of the ridge is substantially constant, and a second region where the width of the bottom portion of the ridge is varied continuously. The second region is placed between the first region and an end face in an optical path.

Furthermore, an optical pickup apparatus of the present invention includes a semiconductor laser device and a light-receiving portion for receiving light output from the semiconductor laser device and reflected from a recording medium. Herein, the semiconductor laser device is formed on a tilted substrate composed of a compound semiconductor, and includes an active layer and two cladding layers interposing the active layer therebetween. One of the cladding layers forms a mesa-shaped ridge. Furthermore, the ridge includes a first region where a width of a bottom portion of the ridge is substantially constant, and a second region where the width of the bottom portion of the ridge is varied continuously. The second region is placed between the first region and an end face in an optical path.

These and other advantages of the present invention will become apparent to those skilled in the art upon reading and understanding the following detailed description with reference to the accompanying figures.

### BRIEF DESCRIPTION OF THE DRAWINGS

FIG. 1 is a schematic cross-sectional view showing an exemplary semiconductor laser device of the present invention.

FIG. 2 is a schematic view showing an exemplary ridge in the semiconductor laser device of the present invention.

FIG. 3 is a view showing an exemplary relationship between a differential resistance Rₛ in current—voltage characteristics and a width of a bottom portion of a ridge in a semiconductor laser device in which the width of the bottom portion of the ridge is substantially the same between one end face and the other end face in an optical path.

FIG. 4 is a view showing an exemplary relationship between a maximum light output and a width of a bottom portion of a ridge in the semiconductor laser device in which the width of the bottom portion of the ridge is substantially the same between one end face and the other end face in an optical path.

FIG. 5 is a view showing an exemplary distribution of an effective refractive index in the semiconductor laser device in which the width of the bottom portion of the ridge is substantially the same between one end face and the other end face in an optical path.

FIGS. 6A and 6B are views showing exemplary distributions of intensity and a carrier concentration in the semiconductor laser device in which the width of the bottom portion of the ridge is substantially the same between one end face and the other end face in an optical path.

FIG. 7 is a view showing exemplary current—light output characteristics in the semiconductor laser device in which the width of the bottom portion of the ridge is substantially the same between one end face and the other end face in an optical path.

FIG. 8 is a view showing exemplary results of a near field before and after the occurrence of kink in the semiconductor laser device in which the width of the bottom portion of the ridge is substantially the same between one end face and the other end face in an optical path.

FIG. 9 is a view showing an exemplary distribution of a carrier concentration in the semiconductor laser device in which the width of the bottom portion of the ridge is substantially the same between one end face and the other end face in an optical path.

FIG. 10 is a view showing an exemplary distribution of a carrier concentration in the semiconductor laser device in which the width of the bottom portion of the ridge is substantially the same between one end face and the other end face in an optical path.

FIG. 11 is a view showing an exemplary relationship between a difference in a local maximum value of a distribution of a carrier concentration and a width of a bottom portion of a ridge in the semiconductor laser device in which the width of the bottom portion of the ridge is substantially the same between one end face and the other end face in an optical path.

FIG. 12 is a view showing an exemplary relationship between a length of a first region and a maximum light output in the semiconductor laser device of the present invention.

FIG. 13 is a view showing an exemplary relationship between a length of a first region and a differential resistance Rₛ in current—voltage characteristics in the semiconductor laser device of the present invention.

FIG. 14 is a view showing exemplary current—light output characteristics in the semiconductor laser device of the present invention and exemplary current—light output characteristics in a conventional semiconductor laser device.

FIGS. 15A to 15F are schematic views showing an exemplary method for producing a semiconductor laser device of the present invention.

FIG. 16 is a schematic view showing an exemplary optical pickup apparatus of the present invention.

FIG. 17 is a schematic view showing another exemplary optical pickup apparatus of the present invention.

FIG. 18 is a schematic cross-sectional view showing an exemplary conventional semiconductor laser device.

### DESCRIPTION OF THE PREFERRED EMBODIMENTS

Hereinafter, the present invention will be described by way of an embodiment with reference to the drawings. In the following embodiment, like components are denoted with like reference numerals, and the repeated description may be omitted.

First, a semiconductor laser device hereinafter, which also may be referred to as a “semiconductor laser”) of the present invention will be described.

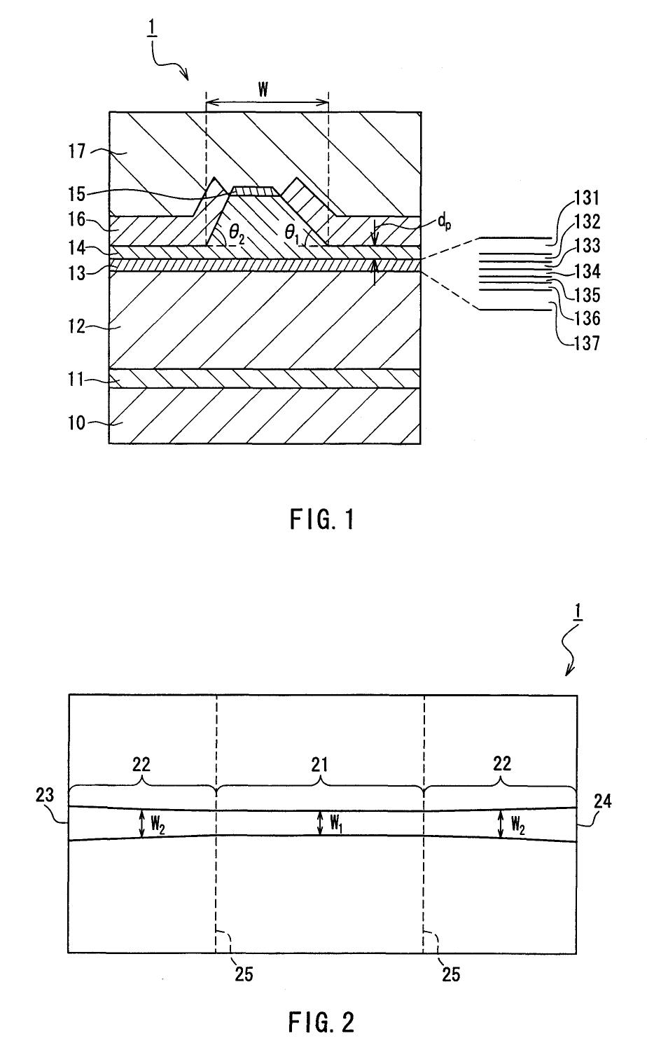

FIG. 1 is a cross-sectional view showing an exemplary semiconductor laser device of the present invention. A semiconductor laser device 1 shown in FIG. 1 is formed on an n-type GaAs substrate 10 having a plane tilted by 10° in a [011] direction from a (100) plane as a principal plane. An n-type GaAs buffer layer 11, an n-type (AlGa)InP first cladding layer 12, an active layer 13, a p-type (AlGa)InP second cladding layer 14, and a p-type GaInP protective layer 15 are stacked successively on the n-type GaAs substrate 10. The semiconductor laser device 1 has a double-hetero structure in which the active layer 13 is interposed between two cladding layers.

Furthermore, the p-type (AlGa)InP second cladding layer 14 forms a ridge having a forward mesa shape on the active layer 13. Furthermore, an n-type AlInP current blocking layer 16 is formed so as to cover side surfaces of the ridge, and a p-type GaAs contact layer 17 is stacked on the n-type AlInP current blocking layer 16 and the p-type GaInP protective layer 15 positioned on an upper portion of the ridge. The active layer 13 shown in the example in FIG. 1 is a strain quantum well active layer composed of an (AlGa)InP first guide layer 131, a GaInP first well layer 132, an (AlGa)InP first barrier layer 133, a GaInP second well layer 134, an (AlGa)InP second barrier layer 135, a GaInP third well layer 136, and an (AlGa)InP second guide layer 137. In the semiconductor laser shown in FIG. 1, angles θ₁ and θ₂ (θ₁ is assumed to be an acute angle) formed by the sides surfaces of the ridge and the principal plane of the substrate are θ₁=44.7° and θ₂=64.7°, respectively, since a tilted substrate (which also is called an off-orientation substrate) having a plane tilted by 10° in a [011] direction from a (100) plane as a principal plane is used. The description of a mole fraction of each of the above-mentioned layers is omitted. An example of the mole fraction will be described later.

In the semiconductor laser device 1 shown in FIG. 1, a current injected from the p-type GaAs contact layer 17 is confined to the ridge portion by the n-type AlInP current blocking layer 16, whereby the current is injected in a concentrated manner into the active layer 13 in the vicinity of a bottom portion of the ridge. Therefore, a population inversion state of carriers required for laser oscillation is realized with an injected current of about tens of mA. At this time, light emitted by re-combination of carriers is confined by the n-type (AlGa)InP first cladding layer 12 and the p-type (AlGa)InP second cladding layer 14 in a direction vertical to a principal plane of the active layer 13. Furthermore, in a direction parallel to the principal plane of the active layer 13, the light is confined by the n-type AlInP current blocking layer 16 with a refractive index smaller than that of the p-type (AlGa)InP second cladding layer 14. Therefore, a semiconductor laser device (of a ridge waveguide type) enabling fundamental transverse mode oscillation, using a ridge as a waveguide, can be obtained.

Furthermore, in the semiconductor laser device 1 shown in FIG. 1, the ridge formed by the p-type (AlGa)InP second cladding layer 14 includes a first region where a width W of a bottom portion of a ridge is substantially constant, and a second region where the width W of the bottom portion of the ridge is varied continuously. Furthermore, the second region is placed between the first region and the end face in an optical path of the semiconductor laser device 1.

In such a semiconductor laser device, a relative light-emitting position with respect to the cross-sectional shape of the ridge, seen in an optical path direction, can be made substantially constant due to the first region where the width of the bottom portion of the ridge is substantially constant. More specifically, a semiconductor laser device can be obtained that is capable of oscillating stably up to a high output and in which an optical axis of a far-field pattern (hereinafter, referred to as an “FFP”) of oscillating laser light is stable. Furthermore, since the width of the ridge can be enlarged using the second region where the width of the ridge is varied continuously, a differential resistance (hereinafter, referred to as “Rₛ”) in current—voltage characteristics of the device can be decreased. Therefore, a semiconductor laser device can be obtained in which an optical axis of the FFP is stabilized and Rₛ is reduced, and which is capable of oscillating in a fundamental transverse mode up to a high output. The “substantially constant” width of the bottom portion of the ridge refers to, for example, that the difference between a maximum value and a minimum value in the width of the bottom portion of the ridge is 20% or less of the maximum value.

The idea of the semiconductor laser device of the present invention will be described.

As described above, although the semiconductor laser device formed on the tilted substrate is excellent in temperature characteristics T₀, the cross-sectional shape of the ridge, seen in an optical path direction, is right-left asymmetrical. Therefore, kink is likely to occur in a high-output state. In order to suppress the occurrence of kink up to a higher light output, there is a method for reducing the asymmetry of a distribution of a carrier concentration. For this purpose, spatial hole burning of carriers only needs to be suppressed by decreasing a stripe width, and increasing the density of an injected current of carriers to a stripe center portion. That is, by decreasing the width of the bottom portion of the ridge, a semiconductor laser device capable of oscillating stably until a higher output can be obtained. The term “right-left” in “right-left asymmetrical” in the present specification refers to “right-left in a cross-section of the semiconductor laser device, seen in an optical path direction, when the substrate of the semiconductor laser device is placed downward as shown in FIG. 1.

Furthermore, in the case of a laser of an effective refractive index waveguide type composed of a current blocking layer, which has a refractive index smaller than that of the second cladding layer forming a ridge and is transparent to oscillating laser light, generally, in order to suppress high-order transverse mode oscillation to obtain stable fundamental transverse mode oscillation, the width of the bottom portion of the ridge preferably is minimized.

However, if the width of the bottom portion of the ridge is decreased, the width of an upper surface of the ridge also becomes small simultaneously. Rₛ of the semiconductor laser device is determined by the width of the upper surface of the ridge in which an injected current is confined most. Therefore, merely by decreasing the width of the bottom portion of the ridge so as to obtain stable oscillation up to a higher output, Rₛ is increased, and an operation voltage may be increased. An increase in an operation voltage increases an operation power. Therefore, the amount of generated heat in the semiconductor laser device is increased, which may lead to degradation of the temperature characteristics T₀ and a decrease in reliability.

Furthermore, in the case of using the semiconductor laser device in an optical disk system, return light reflected from an optical disk may be incident upon the semiconductor laser. When a return light component is increased, mode hopping noise is caused, which may degrade an S/N ratio during reproduction of a signal. In order to suppress this phenomenon, a method for setting oscillating laser light to be multimodal is effective. Generally, in the semiconductor laser device, by superposing high-frequency currents on a driving current, oscillating laser light is set to be multimodal. However, in this case, when Rₛ is increased, a change in an operation current with respect to a change in an operation voltage is decreased. Therefore, a current component with a high-frequency current superposed thereon tends to be decreased. Furthermore, when a change in an operation current is decreased, a change in a wavelength width having a gain that enables oscillation also is decreased. Therefore, the multimode of an oscillation spectrum is lost, which may increase interference noise from the optical disk. That is, an increase in Rₛ may lead to a decrease in reliability of the semiconductor laser device.

In the semiconductor laser device of the present invention, the ridge is divided into the first region and the second region, and the respective widths are controlled, whereby a semiconductor laser device can be obtained in which the influence of the above-mentioned problem is suppressed.

The length of the first region (length in a direction connecting end faces in an optical path) may be, for example, in a range of 5% to 45%, and preferably in a range of 5% to 20% of a resonator length. Furthermore, the length of the second region (length in a direction connecting end faces in an optical path) may be, for example, in a range of 55% to 95%, and more preferably in a range of 80% to 95% of a resonator length. In the case where there are a plurality of second regions, the length of the second region may be the total length of a plurality of second regions. This also applies to the case where there are a plurality of first regions. The value of the resonator length in the semiconductor laser device of the present invention is not particularly limited, and is, for example, in a range of 800 μm to 1500 μm. In the case of obtaining a semiconductor laser device with an output of 100 mW or more, the resonator length may be set to be, for example, in a range of 900 μm to 1200 μm, in terms of suppression of a leakage current.

In the semiconductor laser device of the present invention, in the second region, the width of the bottom portion of the ridge may be increased with distance from the first region. Thus, a semiconductor laser device can be obtained in which an optical axis of the FFP is stabilized and Rₛ is reduced further, and which is capable of oscillating in a fundamental transverse mode up to a high output.

Furthermore, in the semiconductor laser device of the present invention, the second regions may be present between the first region and one end face in an optical path and between the first region and the other end face in the optical path. Thus, a semiconductor laser device can be obtained in which an optical axis of the FFP is stabilized and Rₛ is reduced further, and which is capable of oscillating in a fundamental transverse mode up to a high output. Furthermore, in the semiconductor laser device of the present invention, the width of the bottom portion of the ridge in the first region and the width of the ridge in the second region may be substantially the same at a boundary between the first region and the second region. Thus, a change in a distribution of light intensity at the boundary between the first region and the second region is suppressed, and a waveguide loss can be reduced further. The term “substantially the same” refers to that, at the boundary between the first region and the second region, the difference in a width of the ridge between the regions is, for example, 0.2 μm or less.

FIG. 2 shows an exemplary shape of the ridge in the semiconductor laser device of the present invention. FIG. 2 is a schematic view showing the shape of the ridge seen from the p-type GaAs contact layer 17 side in the semiconductor laser device shown in FIG. 1. In the example shown in FIG. 2, the ridge of the semiconductor laser device 1 includes a first region 21 where a width W₁ of the bottom portion of the ridge is substantially constant and a second region 22 where a width W₂ of the bottom portion of the ridge is varied continuously. Furthermore, in the second region 22, the width W₂ of the bottom portion of the ridge is increased with distance from the first region 21. Furthermore, the second regions 22 are present between the first region 21 and one end face 23 in an optical path and between the first region 21 and the other end face 24 in the optical path. Furthermore, at a boundary 25 between the first region 21 and the second region 22, the width W₁ of the bottom portion of the ridge in the first region 21 is substantially the same as the width W₂ of the bottom portion of the ridge in the second region 22, and side surfaces of the ridge in both the regions are formed continuously.

Due to the above-mentioned configuration, a semiconductor laser device can be obtained in which an optical axis of the FFP is stabilized and with Rₛ and a waveguide loss are reduced further, and which is capable of oscillating in a fundamental transverse mode up to a high output.

In the semiconductor laser device shown in FIG. 1, the thickness, composition, mole fraction, conductivity, and the like of each layer are not particularly limited. They may be set arbitrarily based on the characteristics required as a semiconductor laser device. For example, each layer may be set at the thickness, composition, and mole fraction described below. The numerical value shown in parentheses refers to the thickness of each layer, and the same reference numerals as those in FIG. 1 are used for ease of understanding.

Exemplary mole fraction and thickness of each layer are as follows: n-type GaAs buffer layer 11 (0.5 μM), n-type (Al_{0.7}Ga_{0.3})_{0.51}In_{0.49}P first cladding layer 12 (1.2 μm), p-type (Al_{0.7}Ga_{0.3})_{0.51}In_{0.49}P second cladding layer 14, p-type Ga_{0.51}In_{0.49}P protective layer 15 (50 nm), and p-type GaAs contact layer 17 (3 μm). An example of the active layer 13 is a strain quantum well active layer composed of an (Al_{0.5}Ga_{0.5})_{0.51}In_{0.49}P (50 nm) first guide layer 131, a Ga_{0.48}In_{0.52}P (5 nm) first well layer 132, an (Al_{0.5}Ga_{0.5})_{0.51}In_{0.49}P (5 nm) first barrier layer 133, a Ga_{0.48}In_{0.52}P (5 nm) second well layer 134, an (Al_{0.5}Ga_{0.5})_{0.51}In_{0.49}P (5 nm) second barrier layer 135, a Ga_{0.48}In_{0.52}P (5 nm) third well layer 136, and an (Al_{0.5}Ga_{0.5})_{0.51}In_{0.49}P (50 nm) second guide layer 137. An example of the p-type (Al_{0.7}Ga_{0.3})_{0.51}In_{0.49}P second cladding layer 14 is a second cladding layer in which a distance between a p-type GaInP protective layer 15 placed on an upper portion of the ridge and an active layer 13 is 1.2 μm, and a distance dₚ between the bottom portion of the ridge and the active layer is 0.2 μm. An example of the thickness of the n-type AlInP current blocking layer 16 is 0.7 μm. In this example, the width of the upper surface of the ridge is smaller by about 1 μm compared with the width of the bottom portion of the ridge.

The active layer 13 is not particularly limited to the strain quantum well active layer as shown in the above example. For example, a non-strain quantum well active layer or a bulk active layer may be used. Furthermore, there is no particular limit to the conductivity of the active layer 13. The active layer 13 may be in a p-type or an n-type. The active layer 13 may be an undoped layer.

Furthermore, as in the example shown in FIG. 1, if a current blocking layer transparent to oscillating laser light is used, a waveguide loss can be reduced, and an operation current value also can be decreased. In this case, the distribution of light propagating through a waveguide can penetrate largely the current blocking layer. Therefore, the difference between the effective refractive index (Δn) inside the stripe region and that outside the stripe region can be set to be in the order of 10⁻³. Furthermore, Δn can be controlled minutely by regulating the distance dₚ shown in FIG. 1. Thus, a semiconductor laser device can be obtained in which an operation current value is reduced, and which is capable of oscillating stably up to a high output. The range of Δn is, for example, in a range of 3×10⁻³ to 7×10⁻³. In this range, the semiconductor laser device can oscillate in a fundamental transverse mode stably up to a high output.

The value of an angle (tilt angle) θ from a particular crystal plane ((100) plane in the example shown in FIG. 1) in the substrate is not limited to 10° in the example shown in FIG. 1 and is not particularly limited. For example, the tilt angle may be set in a range of 7° to 15°. In this range, a semiconductor laser device more excellent in the temperature characteristics To can be obtained. When the tilt angle is smaller than this range, a natural superlattice is formed, whereby the bandgap of the cladding layer is decreased, which may decrease the temperature characteristics T₀. Furthermore, when the tilt angle is larger than the above range, the asymmetry of the cross-sectional shape of the ridge, seen in an optical path direction, is increased, which also may decrease the crystallinity of the active layer.

In the semiconductor laser device of the present invention, the width of the bottom portion of the ridge in the first region may be in a range of 1.8 μm to 2.5 μm. According to such a configuration, spatial hole burning of carriers can be suppressed further in the first region where the width of the bottom portion of the ridge is constant. Therefore, a semiconductor laser device with the occurrence of kink suppressed until a higher output can be obtained.

Furthermore, in the semiconductor laser device of the present invention, the width of the bottom portion of the ridge in the second region may be in a range of 2.4 μm to 3 μm. According to such a configuration, a high-order transverse mode can be cut off more effectively while the increase in Rₛ is suppressed more in the second region. Therefore, a semiconductor laser device capable of oscillating in a fundamental transverse mode until a higher output can be obtained.

In the semiconductor laser device of the present invention, the difference between the width of the bottom portion of the ridge in the first region and the maximum value of the width of the bottom portion of the ridge in the second region may be 0.5 μm or less. According to such a configuration, a semiconductor laser device can be obtained in which an increase in a waveguide loss involved in a change in a distribution of light intensity is suppressed and a waveguide loss is reduced further in the second region.

In the semiconductor laser device of the present invention, the active layer in the vicinity of the end face may be disordered by the diffusion of impurities. According to such a configuration, the bandgap of the active layer in the vicinity of the end face is increased to obtain an end face window structure transparent to laser light. Therefore, a semiconductor laser device can be obtained in which Catastrophic Optical Damage (so-called C.O.D.) is unlikely to occur even with a higher light output.

As an impurity, for example, Si, Zn, Mg, 0, or the like may be used. Furthermore, the diffusion amount (doping amount) of the impurity is, for example, in a range of 1×10¹⁷ cm⁻³ to 1×10²⁰ cm⁻³. The diffusion distance of the impurity may be, for example, in a range of 10 μm to 50 μm from the end face of a semiconductor laser device.

Hereinafter, the present invention will be described in more detail by using experimental results with respect to a semiconductor laser device. Each experiment described hereinafter was conducted by a general procedure in the field of a semiconductor laser device, unless otherwise specified.

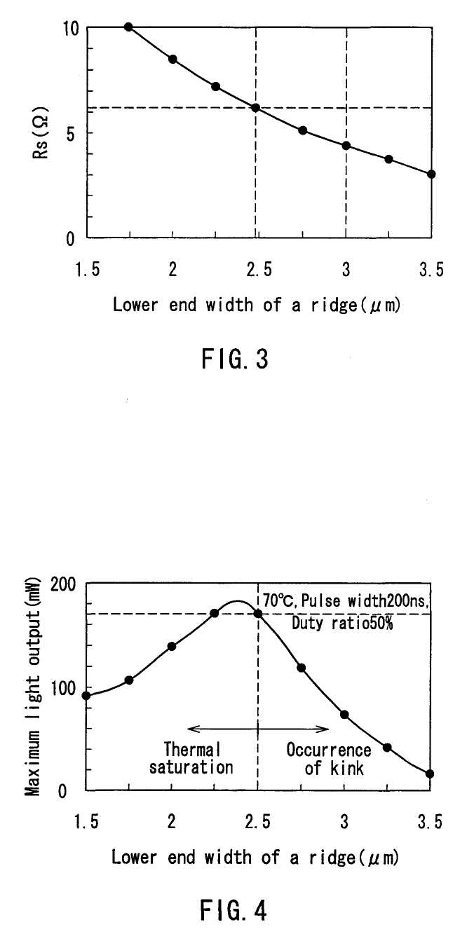

First, in a semiconductor laser device having the same cross-sectional configuration and mole fraction as those of the example shown in FIG. 1, the width of a bottom portion of a ridge was set to be substantially the same between one end face and the other end face in an optical path i.e., in the absence of the second region described above, where the width of the bottom portion of the ridge is varied continuously), whereby the relationship between Rₛ and the width of the bottom portion of the ridge (lower end width of the ridge) was checked. FIG. 3 shows the results.

As shown in FIG. 3, it was found that when the width of the bottom portion of the ridge is 2.4 μm or more, Rₛ is 6.5Ω or less.

Generally, the value of Rₛ required for a light source of at least quadruple-speed DVD system is set to be 6.5Ω or less. Furthermore, in the case where the width of the bottom portion of the ridge exceeds 3 μm, it is considered that high-order transverse mode oscillation may occur. Therefore, the following was found: when the width of the bottom portion of the ridge is in a range of 2.4 μm to 3 μm, a semiconductor laser device can be obtained in which an increase in Rₛ is suppressed further, and which is capable of oscillating stably in a transverse mode. In this case, the width of the upper surface of the ridge is in a range of 1.0 μm to 1.6 μm.

Next, in a semiconductor laser device having the same cross-sectional configuration and mole fraction as those of the example shown in FIG. 1, the width of a bottom portion of a ridge is set to be substantially the same between one end face and the other end face in an optical path, whereby the relationship between the maximum light output during pulse driving and the width of the bottom portion of the ridge was checked. FIG. 4 shows the results. Oscillation of laser light was performed at a temperature of 70° C. for the semiconductor laser device, a pulse width of 200 ns, and a duty ratio of 50%.

As shown in FIG. 4, it was found that, in the case where the width of the bottom portion of the ridge exceeds 2.5 μm, the maximum light output is determined by a light output in which kink occurs. Furthermore, as the width of the bottom portion of the ridge is increased, the light output value at which kink occurs was decreased. On the other hand, it was found that, in the case where the width of the bottom portion of the ridge is 2.5 μm or less, a light output is limited by thermal saturation although kink does not occur. Furthermore, it was found that the light output for causing thermal saturation tends to be smaller. The reason for this may be as follow: as the width of the ridge bottom portion is smaller, Rₛ is increased. From these results, it was found that, when the width of the bottom portion of the ridge is 2.5 μm or less, a semiconductor laser device can be obtained in which the occurrence of kink is suppressed. However, it was simultaneously found that, as the width of the bottom portion of the ridge is decreased further, thermal saturation is more likely to occur.

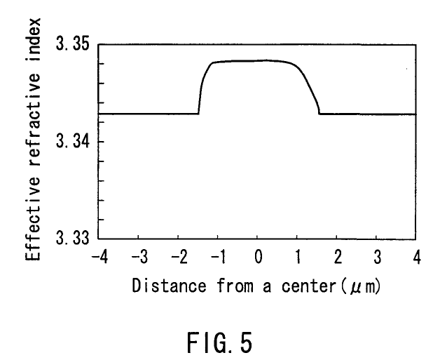

Next, in a laser having the same cross-sectional configuration as that of the example shown in FIG. 1, the width of the bottom portion of the ridge was set to be substantially the same between one end face and the other end face in an optical path, whereby the cause for kink was studied. As an example, FIG. 5 shows a distribution of an effective refractive index in the case where the width of the bottom portion of the ridge is 2.7 μm and the distance dₚ is 0.2 μm. The distribution of the effective refractive index shown in FIG. 5 corresponds to that in a horizontal direction of a cross-section seen in an optical path direction in the semiconductor laser device shown in FIG. 1. The center refers to that in an opening of the bottom portion of the ridge. The distribution of the effective refractive index was obtained by calculation.

As shown in FIG. 5, it is found that the effective refractive index on a steep slope side (θ₂ side) among the side surfaces of the ridge is more steeply changed with respect the distance from the center, compared with the effective refractive index on a gentle slope side (θ₁ side). Thus, it is considered that the occurrence of kink is induced when the distribution of an effective refractive index becomes right-left symmetrical.

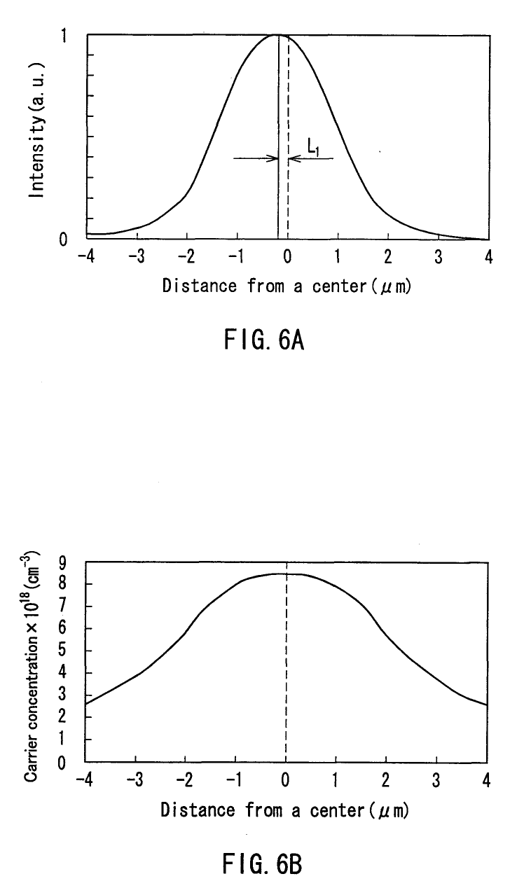

Next, FIGS. 6A and 6B show an example of a distribution of light-emitting intensity and an example of a distribution of a carrier concentration, respectively, in a state of an oscillation threshold value (room temperature, continuous oscillation (CW), operation current value 35 mA) in a laser having the same cross-sectional configuration as that of the example shown in FIG. 1. Each distribution shown in FIGS. 6A and 6B corresponds to that in a horizontal direction of a cross-section seen in an optical path direction in the semiconductor laser device shown in FIG. 1. The center refers to that in an opening in the bottom portion of the ridge.

As shown in FIG. 6A, it is understood that the peak position of light-emitting intensity is shifted by 0.18 μm from the center of the bottom portion of the ridge to the steep slope side (θ₂ side) (L₁ shown in FIG. 6A). When an injected current is increased in this state, for example, set to be in a high output state of 100 mW or more, whereby spatial hole burning of carriers occurs, stimulated emission occurs mainly on the steep slope side among the side surfaces of the ridge. Therefore, the distribution of a carrier concentration shows right-left asymmetry in which the carrier concentration is relatively large on the gentle slope side, as shown in FIG. 6B. Thus, when a gain of light intensity received from the state of the distribution of a carrier concentration is increased under the condition that a carrier concentration is unevenly distributed on the gentle slope side of the ridge, the distribution of light intensity moves to the gentle slope side of the ridge, causing kink.

When kink occurs once, and the distribution of light intensity moves largely to the gentle slope side, injected carriers are lost remarkably on the gentle slope side of the ridge due to the re-combination caused by stimulated emission. Therefore, the distribution of a carrier concentration on the steep slope side of the ridge is increased relatively, whereby the distribution of light intensity returns to substantially the original state.

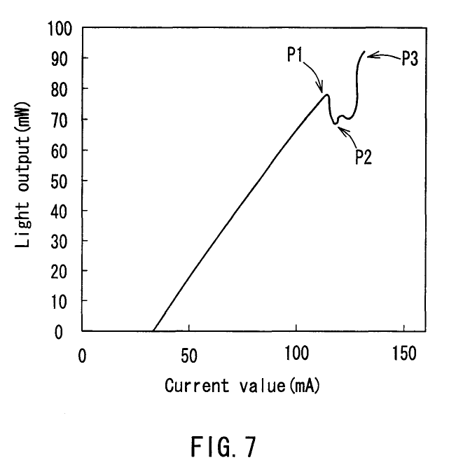

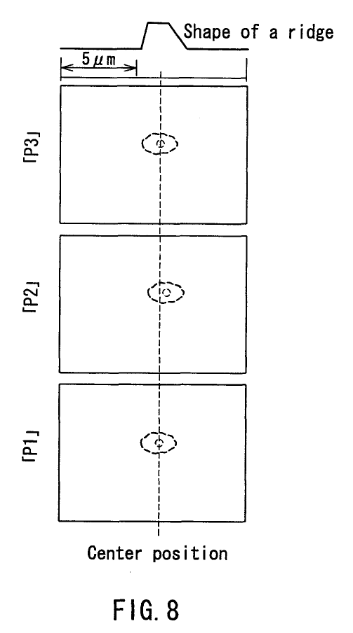

FIGS. 7 and 8 show observation results (which shows the above-mentioned process) of current—light output characteristics and a distribution pattern (near field) of light intensity at room temperature and in a CW state. Immediately before kink occurs (P1 shown in FIGS. 7 and 8), the center (peak position) of the distribution of light intensity is positioned substantially at the center of the bottom portion of the ridge. When kink occurs (P2), the peak position of the distribution of light intensity moves to the gentle slope side of the ridge, causing a discontinuous decrease in light output (light-emitting efficiency). Thereafter, the gain on the steep slope side of the ridge becomes relatively higher than that on the gentle slope side of the ridge. Therefore, the distribution of light intensity returns to the original position (P3), and the light output (light-emitting efficiency) also returns to substantially the original state.

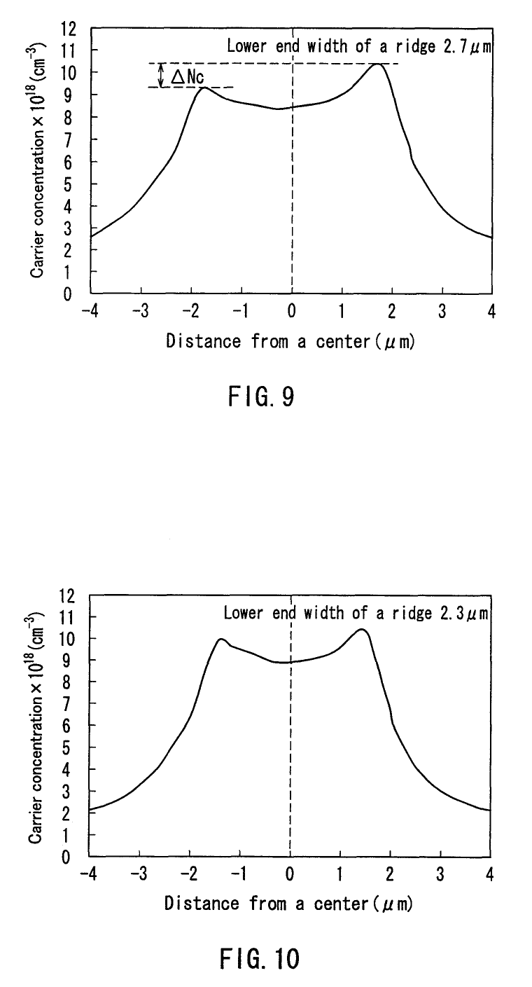

Furthermore, in the case of using a tilted substrate, the peak position of a distribution pattern of light intensity and the peak position of a distribution pattern of a carrier concentration are placed at positions shifted from each other, as shown in FIGS. 6A and 6B. Therefore, the following is known from calculation: the distribution of a carrier concentration in the active layer becomes right-left asymmetrical with respect to a cross-section seen in an optical path direction in the semiconductor laser device. FIG. 9 shows calculation results. FIG. 9 shows a distribution of a carrier concentration at room temperature, CW, and 50 mW, in the semiconductor laser device having the same cross-sectional configuration and mole fraction as those in the example shown in FIG. 1. The distribution shown in FIG. 9 corresponds to that in a horizontal direction of a cross-section seen in an optical path direction in the semiconductor laser device shown in FIG. 1, and the center refers to that in an opening of the bottom portion of the ridge. Furthermore, the width of the bottom portion of the ridge is set to be substantially the same (2.7 μm) between one end face and the other end face in an optical path.

As shown in FIG. 9, it is understood that a difference (ΔNc) of a local maximum value of a carrier concentration distribution with respect to the center is about 1.3×10¹⁸ cm⁻³.

In contrast, as shown in FIG. 10, it is understood that, in the case where the width of the bottom portion of the ridge is decreased to a value less than 2.5 μm (i.e., 2.3 μm) (the other conditions are assumed to be the same as those in FIG. 9), ΔNc is decreased to 0.5×10¹⁸ cm⁻³.

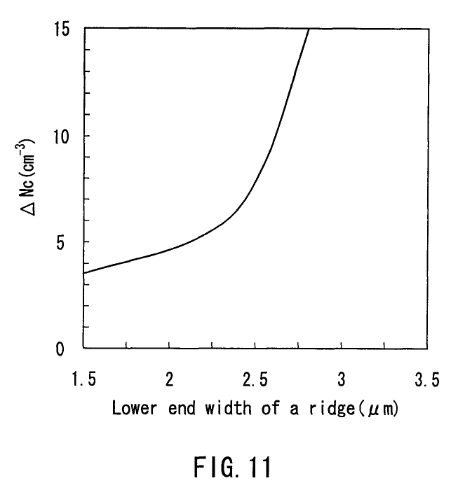

FIG. 11 shows a relationship between ΔNc and the width of the bottom portion of the ridge in the same semiconductor laser device as that in FIG. 9. As shown in FIG. 11, it is understood that by decreasing the width of the bottom portion of the ridge, the asymmetry of the distribution of the carrier concentration in the active layer is corrected. Therefore, by decreasing the width of the bottom portion of the ridge, it is considered that the occurrence of kink is suppressed as shown in FIG. 4.

However, as shown in FIG. 4, Rₛ is increased to cause thermal saturation merely by decreasing the width of the bottom portion of the ridge. Therefore, it is difficult to obtain a semiconductor laser device with a higher output (e.g., 200 mW or more).

According to the present invention, as shown in FIG. 2, the ridge includes the first region 21 where the width of the bottom portion of the ridge is substantially constant, and the second region 22 where the width of the bottom portion of the ridge is varied continuously, whereby the occurrence of kink in the first region is suppressed, and the thermal saturation in the second region is suppressed. Thus, a semiconductor laser device with a higher output can be obtained.

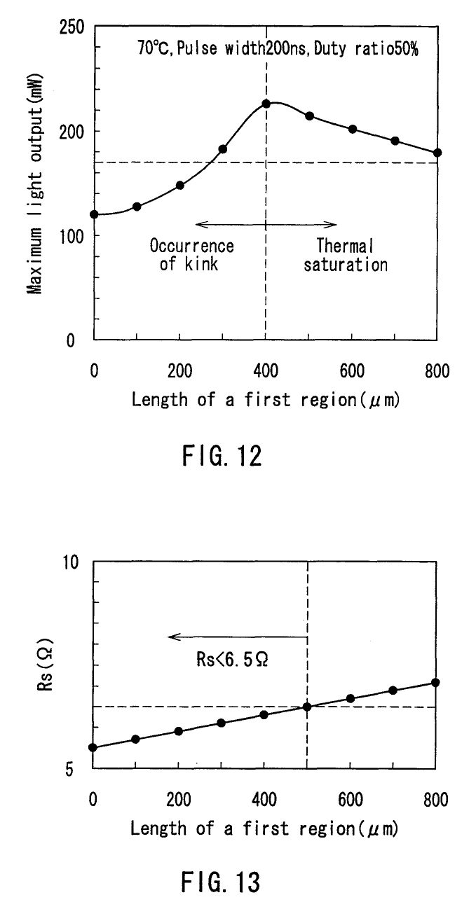

FIG. 12 shows a change in a maximum light output in the case where the resonator length is set to be constant (900 μm), and the length of the first region is varied in the semiconductor laser device shown in FIG. 2. The lengths of the two second regions placed at both ends of the first region were set to be equal to each other. The conditions for oscillating laser light were as follows: 70° C., a pulse width of 200 ns, and a duty ratio of 50%. The width W₁ of the bottom portion of the ridge in the first region was set to be 2.3 μm, the width of the bottom portion of the ridge in the second region was set to be 3 μm or less, and the difference in the width of the bottom portion of the ridge at a boundary between the first region and the second region was set to be 0.4 μm.

As shown in FIG. 12, it was found that the light output in which kink occurs is enhanced when the length of the first region is in a range of 100 μm or more. However, it was found that, when the length of the first region becomes too large, Rₛ is increased, and when the length of the first region is 400 μm or more, the maximum light output is decreased due to thermal saturation. Similarly, FIG. 13 shows a change in Rₛ in the case where the resonator length is set to be constant (900 μm), and the length of the first region is varied. When the length of the first region is increased, the ratio of a region where the width of the upper surface of the ridge is relatively small with respect to the entire ridge is increased, so that Rₛ tends to be increased. In the example shown in FIG. 13, it was found that in order to set Rₛ to be 6.5Ω or less as described above, the length of the first region needs to be 500 μm or less.

From the above-mentioned results, in terms of the suppression of kink, it may be preferable that the length of the first region is 100 μm or more (about 10% or more with respect to the resonator length). Furthermore, in terms of the reduction in Rₛ, it may be preferable that, in the case where the resonator length is in a range of 800 nm to 1200 nm (general range), the length of the first region is in a range of about 400 nm to 600 nm, i.e., about 50% or less with respect to the resonator length.

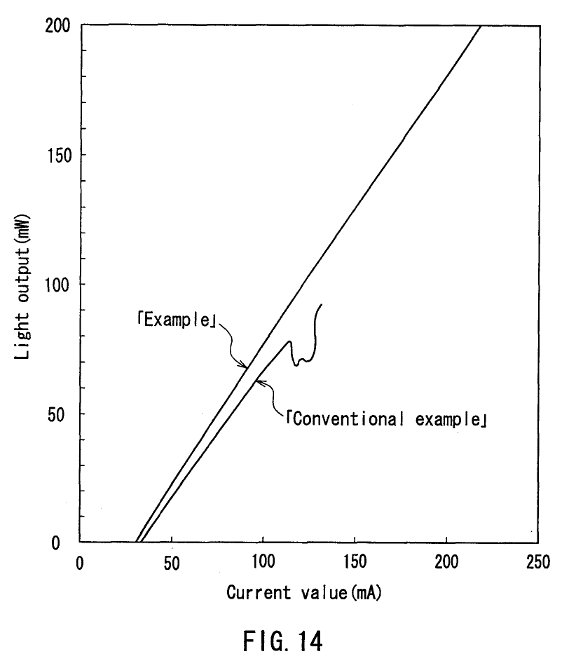

FIG. 14 shows current—light output characteristics (example) at room temperature and in a CW state, in a semiconductor laser device in which the length of the first region is 400 μm, and the length of the second region placed at both ends of the first region is 250 μm (other conditions are assumed to be the same as those in the examples shown in FIGS. 12 and 13). As shown in FIG. 14, it is understood that kink does not occur even when a light output is 200 mW, and stable fundamental transverse mode oscillation is kept. In the conventional example shown in FIG. 14, the width of the ridge is the same between one end face and the other end face in an optical path, which corresponds to current—light output characteristics (room temperature, CW) in the semiconductor laser device having the characteristics shown in FIG. 7.

The example shown in FIG. 14 has a window structure in which Zn is diffused in the active layer in the vicinity of the end faces at a doping amount of 1×10¹⁹ cm⁻³, and the regions of the active layer in the vicinity of the end faces are disordered with impurities. Therefore, C.O.D. that is a phenomenon in which the end faces are broken with a light output did not occur even at an output of 200 mW or more.

Next, a method for producing a semiconductor laser device of the present invention will be described.

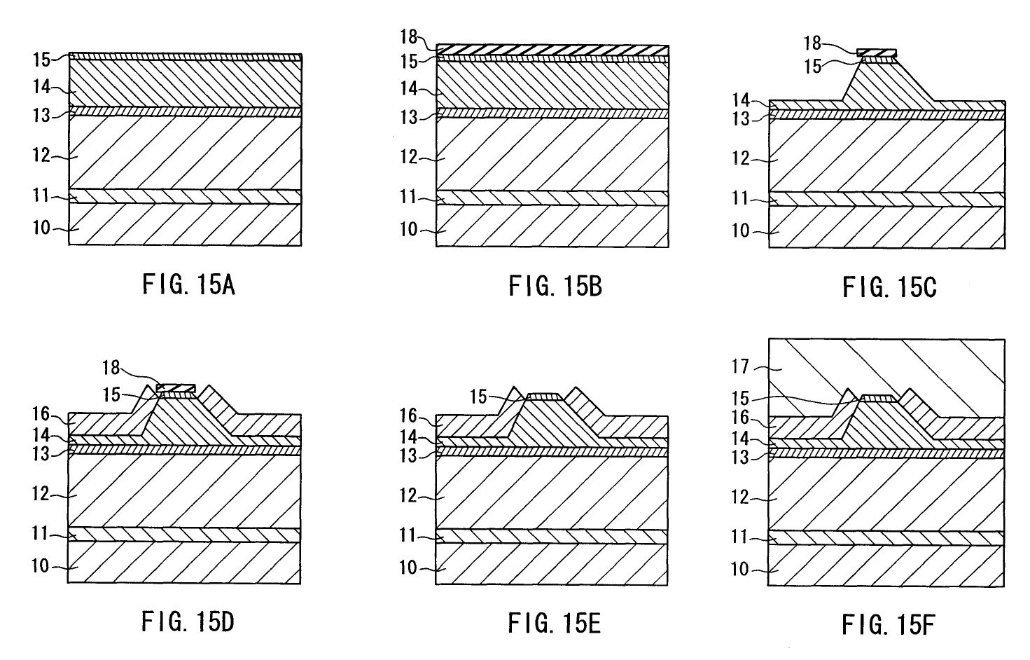

FIGS. 15A to 15F are cross-sectional views illustrating an exemplary method for producing a semiconductor laser device of the present invention.

First, an n-type GaAs buffer layer 11 (0.5 μm), an n-type (AlGa)InP first cladding layer 12 (1.2 μm), an active layer 13, a p-type (AlGa)InP second cladding layer 14, and a p-type GaInP protective layer 15 (50 nm) are formed on an n-type GaAs substrate 10 having a plane tilted by 10° in a [011] direction from a (100) plane as a principal plane (FIG. 15A). Herein, the numerical values in parentheses represent the thickness of each layer. The active layer 13 may be chosen to be similar to, for example, the above-mentioned example of a strain quantum well active layer. The mole fraction of each layer may be chosen to be similar to, for example, the above-mentioned example. For forming each layer, for example, a metal organic chemical vapor deposition (MOCVD) method or a molecular beam epitaxy (MBE) method may be used.

Next, a silicon oxide film 18 is deposited on the p-type GaInP protective layer 15 that is an uppermost layer of the stack composed of each of the above-mentioned layers (FIG. 15B). The deposition may be performed by, for example, a thermal chemical-vapor deposition (CVD) method (atmospheric pressure, 370° C.). The thickness thereof is, for example, 0.3 μm.

Then, regions in the vicinity of end faces of the silicon oxide film 18 (e.g., the regions with a width of 50 μm from the end faces) are removed to expose the p-type GaInP protective layer 15. Then, impurity atoms such as Zn are thermally diffused in the exposed portion, whereby the regions in the vicinity of the end faces of the active layer 13 are disordered.

Next, the silicon oxide film 18 is patterned in a predetermined shape. The patterning may be performed by, for example, a combination of photolithography and dry etching. The predetermined shape may be, for example, the same as the shape of the ridge in the semiconductor laser device of the present invention. For example, the silicon oxide film 18 may be patterned in the shape of the ridge shown in FIG. 2. Then, using the silicon oxide film 18 patterned in the above-mentioned predetermined shape, the p-type GaInP protective layer 15 is etched with a hydrochloric acid etchant, and then, the p-type AlGaInP second cladding layer 14 is etched with a sulfuric acid or hydrochloric acid etchant to form a mesa-shaped ridge (FIG. 15C).

Then, using the silicon oxide film 18 as a mask, an n-type AlInP current blocking layer 16 is selectively grown on the p-type AlGaInP second cladding layer 14 (FIG. 15D). The thickness of the n-type AlInP current blocking layer 16 is, for example, 0.7 μm. As a growing method, for example, the MOCVD method may be used.

Next, the silicon oxide film 18 is removed with hydrofluoric acid etchant (FIG. 15E).

Then, a p-type GaAs contact layer 17 is deposited by the MOCVD method or the MBE method (FIG. 15F).

Thus, the semiconductor laser device of the present invention can be produced.

Hereinafter, an optical pickup apparatus of the present invention will be described.

The optical pickup apparatus of the present invention includes the above-mentioned semiconductor laser device of the present invention, and a light-receiving portion for receiving light output from the semiconductor laser device and reflected from a recording medium. According to this configuration, an optical pickup apparatus can be obtained in which the optical axis of an FFP is stabilized and which is capable of oscillating in a fundamental transverse mode up to a high output.

The optical pickup apparatus of the present invention further includes a light-splitting portion for splitting the reflected light, and the light-receiving portion may receive the reflected light split by the light-splitting portion.

Furthermore, in the optical pickup apparatus of the present invention, the semiconductor laser device and the light-receiving portion may be formed on the same substrate. A smaller optical pickup apparatus can be obtained.

Furthermore, the optical pickup apparatus of the present invention further may include, on the substrate, an optical element that reflects light output from the semiconductor laser device in a direction normal to a principal plane of the substrate. The optical element is not particularly limited, and for example, a reflection mirror may be used.

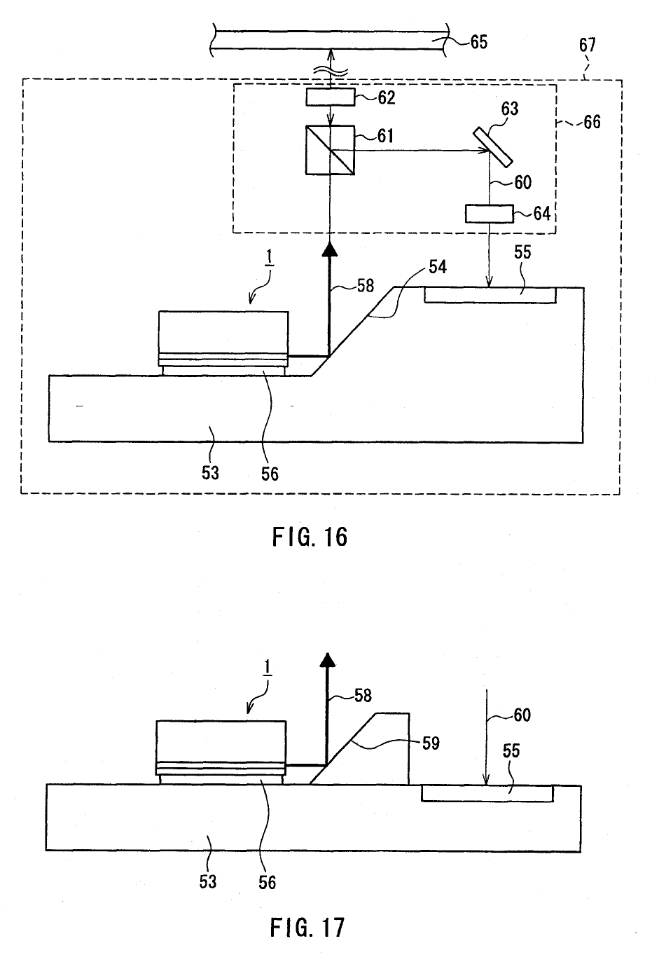

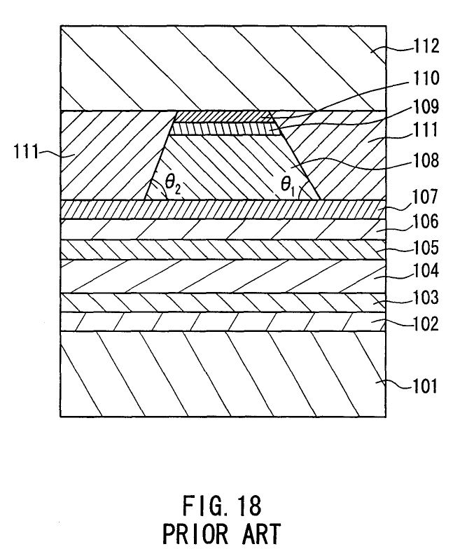

FIG. 16 is a schematic view showing an example of the optical pickup apparatus of the present invention. An optical pickup apparatus 67 shown in FIG. 16 includes a semiconductor laser device 1, and a light-receiving portion (photodetector 55) for receiving reflected light 60 obtained from laser light 58 output from the semiconductor laser device 1 and reflected from a recording medium 65. The semiconductor laser device 1 corresponds to the semiconductor laser device of the present invention. The photodetector 55 is, for example, a photodiode. Furthermore, in the example shown in FIG. 16, in order to suppress the influence of the reflection of the laser light 58 from the surface of a substrate 53, the semiconductor laser device 1 is placed on a base 56. The semiconductor laser device 1 has an optical axis of a FFP stabilized and is capable of oscillating in a fundamental transverse mode up to a high output, as described above. Therefore, the semiconductor laser device 1 can be applied to an optical pickup apparatus that can handle optical disks in various formats such as a DVD.

In the optical pickup apparatus 67 shown in FIG. 16, the photodetector 55 that is a light-receiving portion and the semiconductor laser device 1 are formed on the same substrate 53. Therefore, the optical pickup apparatus 67 can be miniaturized.

The optical pickup apparatus 67 shown in FIG. 16 includes an optical element 54 that reflects the laser light 58 output from the semiconductor laser device 1 in a direction normal to the principal plane of the substrate 53. The optical element 54 is a device obtained by, for example, processing the surface of the substrate 53 by wet etching so that crystal orientation is exhibited.

The optical pickup apparatus 67 shown in FIG. 16 further includes an optical system 66 including a beam splitter 61 that is a light-splitting portion. The laser light 58 output from the semiconductor laser device 1 passes through the beam splitter 61 and the objective lens 62 to be incident upon the recording medium 65. The light reflected from the recording medium 65 is incident upon the beam splitter 61 again to be split. The split reflected light 60 passes through the reflection mirror 63 and a condensing lens 64 to be incident upon the photodetector 55, and is read as a light signal.

Thus, the optical pickup apparatus of the present invention further may include an optical system that allows output laser light to be incident upon a recording medium and guides the light reflected from the recording medium to a light-receiving portion. An example of the above-mentioned optical system corresponds to the optical system 66 including a light-splitting portion as shown in FIG. 16. The specific configuration of the optical system can be chosen arbitrarily without being limited to the example shown in FIG. 16. For example, the optical system may not include a light-splitting portion, and may include a plurality of lens groups. The beam splitter may be a hologram element.

In addition, a light-splitting element for splitting the laser light 58 into a plurality of beams (e.g., three beams: more specifically, one main beam and two sub-beams) may be placed between the beam splitter 61 that is a light-splitting portion and the semiconductor laser device 1. In the case of placing the light-splitting element, the respective split beams can be used for a focus control signal, a tracking error detection signal, and the like. Therefore, recording/reproducing with respect to optical disks in various formats (e.g., DVD-ROM, DVD-RW, DVD-R, DVD-RAM, etc.) can be performed in one pickup apparatus.

Furthermore, the optical system may include an element in which a beam splitter is integrated with a light-splitting element, for example, an optical element in which a light-splitting element is formed on one surface, and a hologram element is formed on the other surface. Thus, a smaller optical pickup apparatus can be obtained.

FIG. 17 is a schematic view showing another exemplary optical pickup apparatus of the present invention. In the optical pickup apparatus shown in FIG. 17, the semiconductor laser device 1 and the photodetector 55 are formed on the same substrate 53. Furthermore, the optical pickup apparatus includes a reflection mirror 59 that reflects laser light 58 output from the semiconductor laser device 1 in a direction normal to the principal plane of the substrate 53. In order to suppress the influence of the reflection of the laser light 58 from the surface of the substrate 53, the semiconductor laser device 1 is placed on the base 56. According to such a configuration, the same effects as those of the optical pickup apparatus shown in FIG. 16 can be obtained. In FIG. 17, the optical system and the recording medium are omitted. For example, they may be the same as those in FIG. 16.

In the present specification, in order to describe the semiconductor laser device and the method for producing the same, and the optical pickup apparatus of the present invention, a GaAnInP semiconductor laser device has been described as a representative example. However, the present invention is not limited to the above semiconductor laser device. As long as the semiconductor laser device is of a ridge waveguide type formed on a tilted substrate, it can be applied even with another composition and configuration.

Thus, according to the present invention, a semiconductor laser device can be provided, in which an optical axis of an FFP is stabilized and which is capable of oscillating in a fundamental transverse mode up to a high output.

Furthermore, by using the semiconductor laser device of the present invention, an optical pickup apparatus can be provided, in which an optical axis of FFP is stabilized and which is capable of being operated by fundamental transverse mode oscillation up to a high output.

The invention may be embodied in other forms without departing from the spirit or essential characteristics thereof. The embodiments disclosed in this application are to be considered in all respects as illustrative and not limiting. The scope of the invention is indicated by the appended claims rather than by the foregoing description, and all changes which come within the meaning and range of equivalency of the claims are intended to be embraced therein.

1. A semiconductor laser device formed on a tilted substrate composed of a compound semiconductor, comprising an active layer and two cladding layers interposing the active layer therebetween,
wherein one of the cladding layers forms a mesa-shaped ridge,
the ridge includes a first region where a width of a bottom portion of the ridge is substantially constant along an optical path direction, and a second region where the width of the bottom portion of the ridge is varied continuously along the optical path direction, and
the second region is placed between the first region and an end face in an optical path.

2. The semiconductor laser device according to claim 1, wherein the width of the bottom portion of the ridge in the second region is increased with distance from the first region.

3. The semiconductor laser device according to claim 1, wherein the second region is placed between the first region and one end face in the optical path, and between the first region and the other end face in the optical path.

4. The semiconductor laser device according to claim 1, wherein the width of the bottom portion of the ridge in the first region is in a range of 1.8 μm to 2.5 μm.

5. The semiconductor laser device according to claim 1, wherein the width of the bottom portion of the ridge in the second region is in a range of 2.4 μm to 3 pm.

6. The semiconductor laser device according to claim 1, wherein, at a boundary between the first region and the second region, the width of the bottom portion of the ridge in the first region is substantially the same as that in the second region.

7. The semiconductor laser device according to claim 1, wherein a difference between the width of the bottom portion of the ridge in the first region and a maximum value of the width of the bottom portion of the ridge in the second region is 0.5 μm or less.

8. The semiconductor laser device according to claim 1, wherein the active layer is formed of a quantum well structure.

9. The semiconductor laser device according to claim 1, wherein the active layer in a vicinity of the end face in the optical path is disordered by diffusion of impurities.

10. An optical pickup apparatus, comprising a semiconductor laser device and a light-receiving portion for receiving light output from the semiconductor laser device and reflected from a recording medium,
wherein the semiconductor laser device is formed on a tilted substrate composed of a compound semiconductor, and includes an active layer and two cladding layers interposing the active layer therebetween,
one of the cladding layers forms a mesa-shaped ridge,
the ridge includes a first region where a width of a bottom portion of the ridge is substantially constant along an optical path direction, and a second region where the width of the bottom portion of the ridge is varied continuously along the optical path direction, and
the second region is placed between the first region and an end face in an optical path.

11. The optical pickup apparatus according to claim 10, further comprising a light-splitting portion for splitting the reflected light,
wherein the light-receiving portion receives the reflected light split by the light-splitting portion.

12. The optical pickup apparatus according to claim 10, wherein the semiconductor laser device and the light-receiving portion are formed on the same substrate.

13. The optical pickup apparatus according to claim 12, further comprising an optical element,
wherein the optical element reflects light output from the semiconductor laser device in a direction normal to a principal plane of the substrate.

14. The optical pickup apparatus according to claim 13, wherein the optical element is a reflection mirror.

15. The semiconductor laser device according to claim 1, wherein a predetermined width of the first region prevents occurrence of kink in the first region, and a predetermined width of the second region prevents thermal saturation in the second region.

16. The semiconductor laser device according to claim 1, wherein a length of the first region is 10% to 50% with respect to a resonator length.
